(19) United States
(12) Patent Application Publication
(10) Pub. No.: US 2023/0207351 A1
(43) Pub. Date: Jun. 29, 2023

(54) APPARATUS AND METHOD FOR TREATING SUBSTRATE

(71) Applicant: SEMES CO., LTD., Cheonan-si (KR)

(72) Inventors: Seung Un OH, Cheonan-si (KR); In Ki JUNG, Hwaseong-si (KR); Shin Hwa KANG, Suwon-si (KR); Sang Hyeon RYU, Yangpyeong-gun (KR); Young Ho PARK, Incheon (KR)

(73) Assignee: SEMES CO., LTD., Cheonan-si (KR)

(21) Appl. No.: 18/147,416

(22) Filed: Dec. 28, 2022

(30) Foreign Application Priority Data
Dec. 28, 2021 (KR) 10-2021-0189855

(51) Int. Cl. H01L 21/67

(52) U.S. Cl. CPC H01L 21/67115; H01L 21/6715; H01L 21/67259; H01L 21/67253

(57) ABSTRACT

Provided is an apparatus for treating a substrate, which includes: a support unit supporting a substrate; a liquid supply unit supplying a treatment liquid to the substrate supported on the support unit; a heating unit heating a specific location of the substrate by irradiating a laser to the specific location on the substrate supported on the support unit, and swingably moved between the specific location of the substrate, and a waiting location of deviating from the substrate; a coordinate unit disposed below an irradiation end portion to which the laser is irradiated from the heating unit when the heating unit is positioned at the waiting location; and an image module monitoring the laser irradiated from the heating unit, in which the image module calculates a movement distance in which the heating unit is swingably moved on the coordinate unit to measure a first length in a longitudinal direction of the heating unit.

### CROSS-REFERENCE TO RELATED APPLICATIONS

This application claims priority to and the benefit of Korean Patent Application No. 10-2021-0189855 filed in the Korean Intellectual Property Office on Dec. 28, 2021, the entire contents of which are incorporated herein by reference.

### TECHNICAL FIELD

An exemplary embodiment relates to an apparatus and a method for treating a substrate.

### BACKGROUND ART

In order to manufacture a semiconductor device, various processes such as photolithography, etching, ashing, ion injection, and thin-film deposition are performed on a substrate such as a wafer. Various treatment liquids and treatment gasses are used for respective processes. Further, in order to remove the treatment liquid used for treating the substrate from the substrate, a drying process is performed on the substrate.

A photolithography process for forming a pattern on the wafer includes an exposure process. The exposure process is a preliminary work for cutting a semiconductor integrated material attached onto the wafer with a desired pattern. The exposure process may have various purposes such as forming the pattern for the etching, forming the pattern for the ion injection, etc. The exposure process draws the pattern into the wafer with light by using a mask which is a kind of ‘frame’. When the semiconductor integrated material on the wafer, e.g., a resist on the wafer is exposed to the light, a chemical property of the resist is changed according to the pattern by the light and the mask. When a development liquid is supplied to the resist of which the chemical property is changed according to the pattern, the pattern is formed on the wafer.

In order to precisely perform the exposure process, the pattern formed in the mask should be precisely manufactured. In order to identify the pattern in the desired shape or precisely, a worker inspects a pattern formed by using an inspection equipment such as a scanning electron microscope (SEM). However, a large number of patterns are formed in one mask. That is, in order to inspect one mask, a lot of time is required for inspecting all of the large number of patterns.

Therefore, a monitoring pattern which can represent one pattern group including a plurality of patterns is formed in the mask. Further, an anchor pattern which can represent a plurality of pattern groups is formed in the mask. The worker can estimate defects of the patterns formed in the mask through inspection of the anchor pattern. Further, the worker can estimate the defects of the patterns included in one pattern group through inspection of the monitoring pattern.

As such, the worker can effectively shorten a time required for inspecting the mask through the monitoring pattern and the anchor pattern formed in the mask. However, it is preferable that critical dimensions of the monitoring pattern and the anchor pattern are the same as each other in order to increase the accuracy of the mask inspection.

When the etching is performed in order to equalize the critical dimension of the monitoring pattern and the critical dimension of the anchor pattern to each other, excessive etching can occur in the pattern. For example, a difference between an etching rate for the critical dimension of the monitoring pattern and the etching rate for the anchor pattern can occur several times, and the excessive etching can occur in the critical dimension of the monitoring pattern and the critical dimension of the anchor pattern in the process of repeatedly etching the monitoring pattern and/or the anchor pattern in order to reduce such a difference. When an etching process is precisely performed in order to minimize occurrence of the excessive etching, a lot of time is required in the etching process. Therefore, a critical dimension correction process for precisely correcting the critical dimensions of the patterns formed in the mask is additionally performed.

FIG. 1 illustrates a normal distribution for a first critical dimension CDP1 of the monitoring pattern and a second critical dimension CDP2 of the anchor pattern of the mask before a critical dimension correction process which is a last step in a mask manufacturing process is performed. Further, the first critical dimension CDP1 and the second critical dimension CDP2 have a size smaller than a targeted critical dimension. In addition, as can seen referring to FIG. 1, a deviation is intentionally given between the critical dimensions (CD0 of the monitoring pattern and the anchor pattern before the critical dimension correction process is performed. In addition, the anchor pattern is additionally etched in the CD correction process to equalize the CDs of both patterns.

In the CD correction process, an etching chemical liquid is supplied onto the substrate so that the first CD CDP1 and the second CD CDP2 become the target CD. However, when the etching chemical liquid is uniformly supplied onto the substrate, even though any one of the first CD CDP1 and the second CD CDP2 can reach the targeted CD, the other one of the first CD CDP1 and the second CD CDP2 is difficult to reach the targeted CD. Further, the deviation between the CDP1 and the CDP2 is not reduced.

Meanwhile, a precise control of an optical module that irradiates a laser to a specific location in the substrate is required in order to precisely perform the CD correction process. In general, the optical module moves to a coordinate of a specific location in a preset substrate. However, there is a problem in that it is difficult to accurately irradiate the laser to a specific location within the substrate due to a tolerance which occurs when components in a chamber such as the optical module are installed.

### SUMMARY OF THE INVENTION

An object of an exemplary embodiment of the present invention is to provide an apparatus and a method for treating a substrate which may efficiently treat a substrate.

Further, an object of the present invention is to provide an apparatus and a method for treating a substrate which may uniformize a CD of a pattern formed on the substrate.

Further, an object of an exemplary embodiment of the present invention is to provide an apparatus and a method for treating a substrate in which a laser may be accurately moved to a desired target position on the substrate.

Further, an object of an exemplary embodiment of the present invention is to provide a process of calculating a length of a heating unit that irradiates the laser to the substrate.

A problem to be solved by the present invention is not limited to the above-described problem, and other technical problems not mentioned may be apparently appreciated by those skilled in the art from the following description.

An exemplary embodiment of the present invention provides an apparatus for treating a substrate. The substrate treating apparatus includes: a support unit supporting a substrate; a liquid supply unit supplying a treatment liquid to the substrate supported on the support unit; a heating unit heating a specific location of the substrate by irradiating a laser to the specific location on the substrate supported on the support unit, and swingably moved between the specific location of the substrate, and a waiting location of deviating from the substrate; a coordinate unit disposed below an irradiation end portion to which the laser is irradiated from the heating unit when the heating unit is positioned at the waiting location; and an image module monitoring the laser irradiated from the heating unit, and the image module calculates a movement distance in which the heating unit is swingably moved on the coordinate unit to measure a first length in a longitudinal direction of the heating unit. The heating unit may include a body having one end at which the irradiation end portion is disposed, a driver providing power for swingably moving the body, and a shaft disposed between the body and the driver, and providing a swing movement axis of the body, and the first length may be a length in which the body is swingably moved based on the swing movement axis of the shaft.

The heating unit may include a body having one end at which the irradiation end portion is disposed, a driver providing power for swingably moving the body, and a shaft disposed between the body and the driver, and providing a swing movement axis of the body, and the first length may be a distance between the swing movement axis of the shaft and a central axis of the irradiation end portion.

The shaft may be coupled to the other end of the body.

The heating unit may further include a laser module provided inside the body, and irradiating the laser, and the image module, and the image module may be provided inside the body, and have the same axis as an irradiation direction of the laser of the laser module. The coordinate unit may include a coordinate system in which a top surface is disposed on the same plane as the top surface of the substrate supported on the support unit, and a support frame supporting the coordinate system.

The heating unit may swingably move the heating unit at a predetermined first angle while the central axis of the irradiation end portion and the central location of the coordinate system.

The coordinate of the central location of the coordinate system may be (0, 0).

The heating unit which is swingably moved at the first angle on the coordinate system may have a movement coordinate, the movement coordinate may be a coordinate of a location in which the central axis of the irradiation end portion of the heating unit is positioned on the coordinate system, and the image module may measure the movement coordinate. The image module may calculate the movement distance in which the central axis of the irradiation end portion of the heating unit is moved by using the movement coordinate. The image module may calculate the first length by using the first angle and the movement distance.

The first length may be calculated through the following equation. (Here, R represents the first length, L represents the movement distance, and θ represents the first angle.)

R=L/(2 sin(θ/2)) <Equation>

The coordinate system may be provided as a line grid.

In the substrate, a first pattern formed in a plurality of cells and a second pattern different from the first pattern outside a zone where the plurality of cells may be formed, and the specific location of the substrate may be the second pattern.

The apparatus may further include a controller, and the controller may control the heating unit so as to minimize a deviation between critical dimensions of the first pattern and the second pattern by irradiating the light to the second pattern.

Another exemplary embodiment of the present invention provides a method for treating a substrate. The substrate treating method may include: a process preparing step; and a process treating step of treating the substrate by irradiating a laser to the substrate by a laser module of a heating unit after the process preparing step, and the process preparing step may include a swing arm length calculating step of calculating a swing arm length of the heating unit by rotating the heating unit on a coordinate system disposed below an irradiation end portion of the heating unit.

The swing arm length calculating step may include matching a central coordinate of the coordinate system and a central axis of the irradiation end portion of the heating unit, rotating the heating unit at a predetermined first angle, calculating a movement distance of the heating unit by an image module provided inside the heating unit, and having the same axis of an irradiation direction of the laser irradiated by the laser module, and calculating a swing arm length of the heating unit through the first angle and the movement distance. The calculating of the swing arm length of the heating unit through the first angle and the movement distance by the image module may be performed through the following equation. (Here, R represents the first length, L represents the movement distance, and θ represents the first angle.)

R=L/(2 sin(θ/2)) <Equation>

The heating unit may include a body having one end at which the irradiation end portion is disposed, a driver providing power for swingably moving the body, and a shaft disposed between the body and the driver, and coupled to the other end of the body and providing a swing movement axis of the body, and the swing arm length may be a length in which the body is swingably moved based on the swing movement axis of the shaft.

The heating unit may include a body having one end at which the irradiation end portion is disposed, a driver providing power for swingably moving the body, and a shaft disposed between the body and the driver, and coupled to the other end of the body and providing a swing movement axis of the body, and the swing arm length may be a distance between the swing movement axis of the shaft and a central axis of the irradiation end portion.

Yet another exemplary embodiment of the present invention provides an apparatus for treating a substrate. The substrate treating apparatus may include: a support unit supporting a substrate; a liquid supply unit supplying a treatment liquid to the substrate supported on the support unit; a heating unit heating a specific location of the substrate by irradiating a laser to the specific location on the substrate supported on the support unit, and swingably moved between the specific location of the substrate, and a waiting location of deviating from the substrate; and a coordinate unit disposed below an irradiation end portion to which the laser is irradiated from the heating unit when the heating unit is positioned at the waiting location, and the heating unit may include a body having one end at which the irradiation end portion is disposed, a driver providing power for swingably moving the body, a shaft disposed between the body and the driver, and providing a swing movement axis of the body, a laser module provided inside the body, and irradiating the laser, and an image module provided inside the body, and monitoring the laser irradiated from the heating unit, and having the same axis as an irradiation direction of the laser of the laser module, and the image module calculates a movement distance in which the heating unit is swingably moved on the coordinate unit at a predetermined first angle to calculate a first length in a longitudinal direction of the heating unit.

According to an exemplary embodiment of the present invention, a substrate can be efficiently treated.

Further, according to an exemplary embodiment of the present invention, a CD of a pattern formed on the substrate can be uniformized.

Further, according to an exemplary embodiment of the present invention, a laser can be accurately moved to a desired target position on the substrate.

Further, according to an exemplary embodiment of the present invention, an apparatus and a method for treating a substrate can be provided, which use a laser which is swingably moved and a rotated substrate support unit so as to accurately irradiate to a target position. Further, according to an exemplary embodiment of the present invention, a heating unit can be precisely controlled by calculating a length of the heating unit irradiating the laser to the substrate.

The effect of the present invention is not limited to the foregoing effects, and non-mentioned effects will be clearly understood by those skilled in the art from the present specification and the accompanying drawings.

### BRIEF DESCRIPTION OF THE DRAWINGS

FIG. 1 is a diagram illustrating a normal distribution a critical dimension of a monitoring pattern and a critical dimension of an anchor pattern.

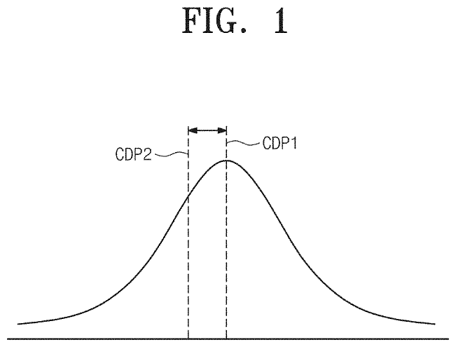

FIG. 2 is a plan view schematically illustrating an apparatus for treating a substrate according to an exemplary embodiment of the present invention.

FIG. 3 is a diagram schematically illustrating a view of a substrate treated in a liquid treating chamber of FIG. 2.

FIG. 4 is a diagram schematically illustrating an exemplary embodiment of the liquid treating chamber of FIG. 2.

FIG. 5 is a diagram illustrating the liquid treating chamber of FIG. 4 viewed from the top.

FIG. 6 is a diagram illustrating a view of a body of a heating unit, a laser module, an image module, and an optical module of FIG. 4.

FIG. 7 is a diagram illustrating the image module of FIG. 6 viewed from the top.

FIG. 8 is a diagram illustrating a coordinate unit and a support unit of the liquid treating chamber of FIG. 4.

FIG. 9 is a diagram illustrating the coordinate unit of FIG. 8 viewed from the top.

FIG. 10 is a flowchart of a method for treating a substrate according to an exemplary embodiment of the present invention.

FIG. 11 is a diagram illustrating a view in which a substrate treating apparatus identifies an error between an irradiation location of a laser and a preset target position in a process preparing step of FIG. 10.

FIG. 12 is a diagram illustrating a view of the substrate treating apparatus performing a location information acquiring step of FIG. 10.

FIG. 13 is a diagram illustrating a view of the substrate treating apparatus performing a liquid treating step of FIG. 10.

FIG. 14 is a diagram illustrating a view of the substrate treating apparatus performing a heating step of FIG. 10.

FIG. 15 is a diagram illustrating a view of the substrate treating apparatus performing a rinse step of FIG. 10.

FIG. 16 is a flowchart schematically illustrating a method for calculating a first length of a heating unit.

FIG. 17 is a diagram illustrating the first length of the heating unit.

FIGS. 18 to 20 are diagrams schematically illustrating each step of FIG. 16.

### DETAILED DESCRIPTION

In the following detailed description, exemplary embodiments of the present invention have been shown and described, simply by way of illustration. As those skilled in the art would realize, the described exemplary embodiments may be modified in various different ways, all without departing from the spirit or scope of the present invention. In the following description of the present invention, a detailed description of known functions and configurations incorporated herein is omitted to avoid making the subject matter of the present invention unclear. Further, the same reference numeral is used for a part which performs a similar function and a similar action through all drawings.

Unless explicitly described to the contrary, the word “include” and variations such as “includes” or “including” will be understood to imply the inclusion of stated elements but not the exclusion of any other elements. In the present application, it should be understood that term “include” or “have” indicates that a feature, a number, a step, an operation, a component, a part or the combination thereof described in the specification is present, but does not exclude a possibility of presence or addition of one or more other features, numbers, steps, operations, components, parts or combinations thereof, in advance. A singular form includes a plural form if there is no clearly opposite meaning in the context. Further, shapes, sizes, and the like of elements in the drawings may be exaggerated for clearer explanation.

Terms including as first, second, and the like are used for describing various components, but the components should not be limited by the terms. The terms are used only for distinguishing one component from the other component. For example, a first component may be referred to as a second component, and similarly, the second component may be referred to as the first component without departing from the scope of the present invention. It should be understood that, when it is described that a component is “connected to” or “accesses” another component, the component may be directly connected to or access the other component or another component may be present therebetween. In contrast, it should be understood that, when it is described that a component is “directly connected to” or “directly access” another component, no component is present between the component and another component. Meanwhile, other expressions describing the relationship of the components, that is, expressions such as “between” and “directly between” or “adjacent to” and “directly adjacent to” should be similarly interpreted.

If it is not contrarily defined, all terms used herein including technological or scientific terms have the same meanings as those generally understood by a person with ordinary skill in the art. Terms which are defined in a generally used dictionary should be interpreted to have the same meaning as the meaning in the context of the related art, and are not interpreted as an ideal meaning or excessively formal meanings unless clearly defined in the present application.

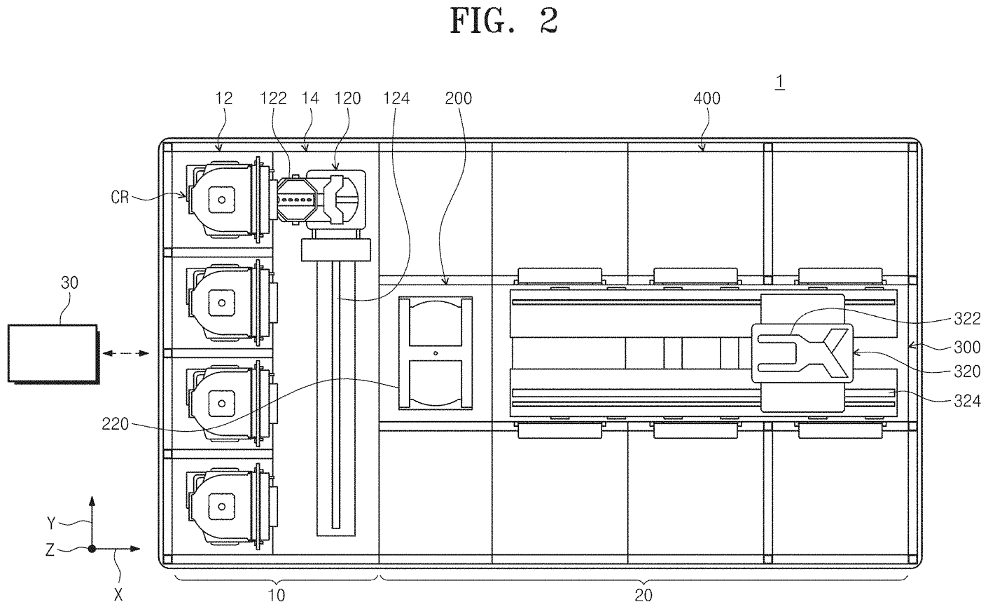

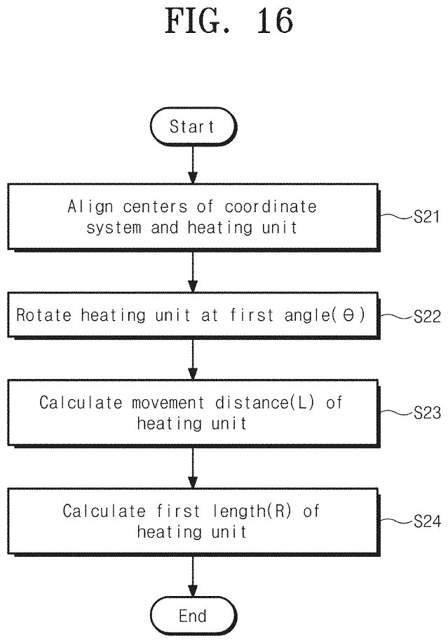

Hereinafter, an exemplary embodiment of the present invention will be described with reference to FIGS. 2 to 17.

FIG. 2 is a plan view schematically illustrating an apparatus for treating a substrate according to an exemplary embodiment of the present invention.

Referring to FIG. 2, the substrate treating apparatus 1 includes an index module 10, a treating module 20, and a controller 30. When viewed from the top, the index module 10 and the treating module 20 are arranged in one direction. Hereinafter, a direction in which the index module 10 and the treating module 20 are placed will be referred to as a first direction X, a direction vertical to the first direction X when viewed from the top will be referred to as a second direction Y, and a direction vertical to both the first direction X and the second direction Y will be referred to as a third direction Z.

The index module 10 may transfer a substrate M to the treating module 20 from a container CR storing the substrate M and store the substrate M of which treating is completed in the treating module 20 in the container CR. A longitudinal direction of the index module 10 is provided as the second direction Y. The index module 10 may include a load port 12 and an index frame 14. The load port 12 may be positioned at an opposite side to the treating module 20 based on the index frame 14. The container CR storing the substrates M may be placed on the load port 12. A plurality of load ports 12 may be provided, and the plurality of load ports 12 may be arranged in the second direction Y.

A sealing container such as a front opening unified pod (FOUP) may be used as the container CR. The container CR may be placed on the load port 12 by a transportation means (not illustrated) such as an overhead transfer, an overhead conveyor, or an automatic guided vehicle or a worker.

An index robot 120 may be provided in the index frame 14. A guide rail 124 in which a longitudinal direction is provided in as the second direction Y may be provided in the index frame 14. The index robot 120 may be provided to be movable on the guide rail 124. The index robot 120 may include an hand 122 on which the substrate M is placed. The hand 122 may be provided to be movable forward and backward, rotatable with the third direction Z as the axis and movable in the third direction Z. A plurality of hands 122 may be provided to be spaced apart from each other in the vertical direction. The plurality of respective hands 122 may be moved independently from each other.

The controller 30 may control the substrate treating apparatus 1. The controller 30 may include a processor controller consisting of a microprocessor (computer) executing a control of the substrate treating apparatus 1, a keyboard for performing a command input operation and the like to manage the substrate treating apparatus 1 by an operator, a user interface consisting of a display and the like for visualizing and displaying an moving situation of the substrate treating apparatus 1, and a storage unit stored with control programs or various data for executing the treatment executed in the substrate treating apparatus 1 by the control of the process controller and programs, that is, treatment recipes for executing the treatment in each configuration unit according to a treatment condition. In addition, the user interface and the storage unit may be connected to the process controller. A treating recipe may be stored in a storage medium in a storage unit. The storage medium may also be a hard disk, and may also be a transportable disk such as a CD-ROM, a DVD, etc., or a semiconductor memory such as a flash memory.

The controller 30 may control the substrate treating apparatus 1 so as to perform the method for treating the substrate described below. For example, the controller 30 may control components provided in the liquid treating chamber 400 so as to perform the substrate treating method described below.

The treating module 20 may include a buffer unit 200, a transfer frame 300, and a liquid treating chamber 400. The buffer unit 200 may provide a space in which the substrate M loaded into the treating module 20 and the substrate M unloaded from the treating module 20 temporarily stay. The transfer frame 300 may provide a space which transfers the substrate M between the buffer unit 200 and the liquid treating chamber 400. The liquid treating chamber 400 performs a liquid treating process of supplying a liquid onto the substrate M and liquid-treating the substrate M. The treating module 20 may further include a drying chamber, and the drying chamber may perform a drying process of drying the substrate M of which liquid-treating is completed.

The buffer unit 200 may be arranged between the index frame 14 and the transfer frame 300. The buffer unit 200 may be positioned at one end of the transfer frame 300. The buffer unit 200 may store a plurality of substrates M therein. A slot (not illustrated) on which the substrate M is placed may be provided inside the buffer unit 200. A plurality of slots (not illustrated) may be provided. A plurality of slots (not illustrated) may be spaced apart from each other in the third direction A. As a result, the plurality of substrates M stored in the buffer unit 200 may be stacked while being spaced apart from each other in the third direction Z.

A front face and a rear face of the buffer unit 200 may be opened. The front face may be a face facing the index module 10 and the rear face may be a face facing the transfer frame 300. The index robot 120 may access the buffer unit 200 through the front face, and the transfer robot 320 to be described below may access the buffer unit 200 through the rear face.

The longitudinal direction of the transfer frame 300 may be provided as the first direction X. The liquid treating chambers 400 may be disposed at both sides of the transfer frame 300. When the treating module 20 includes the drying chamber, the liquid treating chamber 400 may be disposed at one side of the transfer frame 300, and the drying chamber may be disposed at the other side of the transfer frame 300. The liquid treating chamber 400 and the drying chamber may be arranged at a side portion of the transfer frame 300. The transfer frame 300 and the liquid treating chamber 400 and may be arranged in the second direction Y. The transfer frame 300 and the drying chamber and may be arranged in the second direction Y. The liquid treating chambers 400 may be provided an array of A×B (each of A and B is 1 or a natural number larger than 1) at one side or both sides of the transfer chambers 300 in the first direction X and the third direction Z, respectively. The drying chambers 400 may be provided an array of A×B (each of A and B is 1 or a natural number larger than 1) at the other side of the transfer chambers 300 in the first direction X and the third direction Z, respectively.

The transfer frame 300 has the transfer robot 320 and a transfer rail 324. The transfer robot 320 may transfer the substrate M. The transfer robot 320 may transfer the substrate M between the buffer unit 200 and the liquid treating chamber 400. Further, the transfer robot 320 may transfer the substrate M among the buffer unit 200, the liquid treating chamber 400, and the drying chamber. The transfer robot 320 may include a transfer hand 322 on which the substrate M is placed. The substrate M may be placed on the transfer hand 322. The transfer hand 322 may be provided to be movable forward and backward, rotatable with the third direction Z as the axis, and movable in the third direction Z. A plurality of hands 322 may be provided to be spaced apart from each other in the vertical direction. The plurality of hands 322 may move forward and backward independently from each other. The transfer rail 324 may be provided in the longitudinal direction of the transfer frame 300 within the transfer frame 300. As an example, the longitudinal direction of the transfer rail 324 may be provided in the first direction X. The transfer robot 320 may be placed on the transfer rail 324. The transfer robot 320 may be provided in the transfer rail 324 to be movable on the transfer rail 324.

Hereinafter, the substrate M treated by the liquid treating chamber 400 will be described in detail.

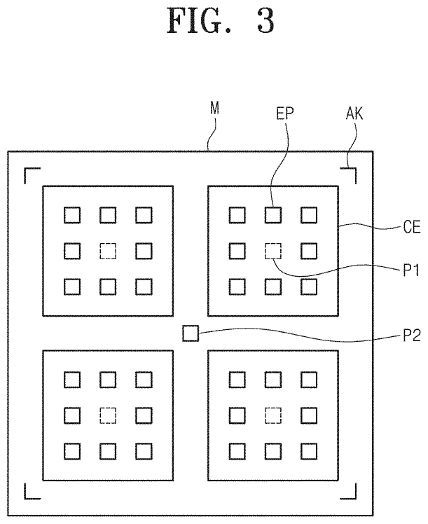

FIG. 3 is a diagram schematically illustrating a view of a substrate treated in a liquid treating chamber of FIG. 2.

Referring to FIG. 3, a treated object treated by the liquid treating chamber 400 may be any one substrate among a wafer, a glass, and a photo mask. For example, the substrate M treated by the liquid treating chamber 400 may be the photo mask which is the ‘frame’ used during the exposure process.

The substrate M may have a square shape. The substrate M may be the photo mask which is the ‘frame’ used during the exposure process. At least one reference mark AK may be marked on the substrate M. For example, a plurality of reference marks AK may be formed at each of corner zones of the substrate M. As an example, the reference mark AK may include first to fourth reference marks. The reference mark AK may be referred to as an align key. The reference mark AK may be a mark used when aligning the substrate M. Further, the reference mark AK may be a mark used for deriving location information of the substrate M. For example, an image module 470 to be described below may acquire an image by photographing the reference mark AK and transmit the acquired image to the controller 30. The controller 30 analyzes the image including the reference mark AK to detect an accurate location of the substrate M. Further, the reference mark AK may be used for determining the location of the substrate M when transferring the substrate M. A cell CE may be formed on the substrate M. The cell CE may include at least one cell CE. A plurality of cells CE may be formed. A plurality of patterns may be formed in each cell CE. The patterns formed in each cell CE may be defined as one pattern group. The patterns formed in the cell CE may include an exposure pattern EP and a first pattern P1. The exposure pattern EP may be used for forming an actual pattern on the substrate M. Further, the first pattern P1 may be a pattern representing the exposure patterns EP formed in one cell CE. Further, when a plurality of cells CE is provided, a plurality of first patterns P1 may be provided. Further, the plurality of first patterns P1 may also be formed in one cell CE. The first pattern P1 may have a shape in which some of the respective exposure patterns EP are combined. The first pattern P1 may also be referred to as a monitoring pattern. Further, the first pattern P1 may also be referred to as critical dimension monitoring micro.

When the worker inspects the first pattern P1 through the scanning electron microscope (SEM), whether shapes of the exposure patterns EP formed in one cell CE are defective may be estimated. Further, the first pattern P1 may be an inspection pattern. Further, the first pattern P1 may also be any one pattern among exposure patterns EP which participate in an actual exposure process. Further, the first pattern P1 may be the exposure pattern which participates in the actual exposure as well as the inspection pattern.

The second pattern P2 may be a pattern representing the exposure patterns EP formed in the entirety of the substrate M. For example, the second pattern P2 may have a shape in which some of the respective first patterns P1 are combined.

When the worker inspects the second pattern P2 through the scanning electron microscope (SEM), whether shapes of the exposure patterns EP formed in one substrate M are defective may be estimated. Further, the second pattern P2 may be the inspection pattern. Further, the second pattern P2 may be an inspection pattern which does not particulate in the actual exposure process. The second pattern P2 may also be referred to as an anchor pattern. Hereinafter, the substrate treating apparatus provided in the liquid treating chamber 400 will be described in detail. Further, hereinafter, it will be described as an example that the treating process performed in the liquid treating chamber 400 performs a fine critical dimension correction (FCC) process which is a last step during manufacturing a mask for the exposure process.

The substrate M which is loaded and treated in the liquid treating chamber 400 may be a substrate M which is pre-treated. The CDs of the first pattern P1 and the second pattern P2 of the substrate M loaded into the liquid treating chamber 400 may be different from each other. For example, the CD of the first pattern P1 may be formed by a first dimension. The CD of the second pattern P2 may be formed by a second dimension. The first dimension may be formed to be larger than the second dimension. For example, the first width may be 69 nm and the second dimension may be 68.5 nm.

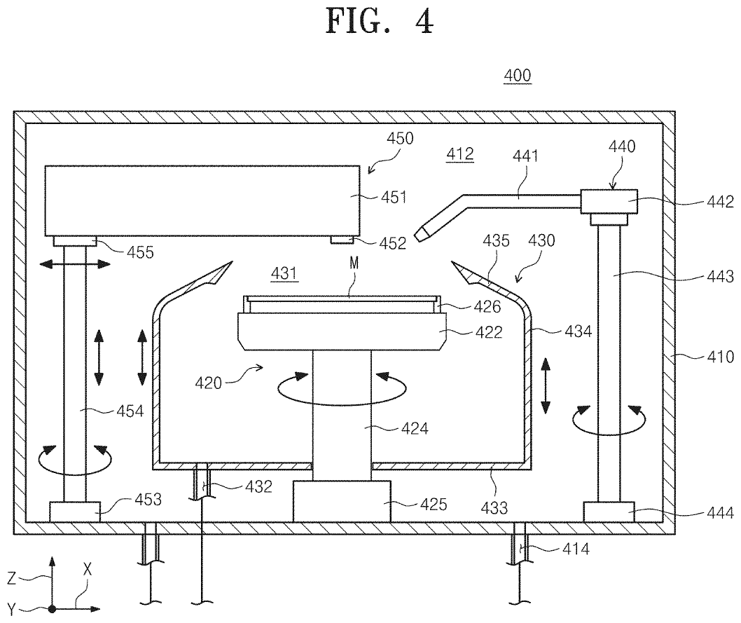

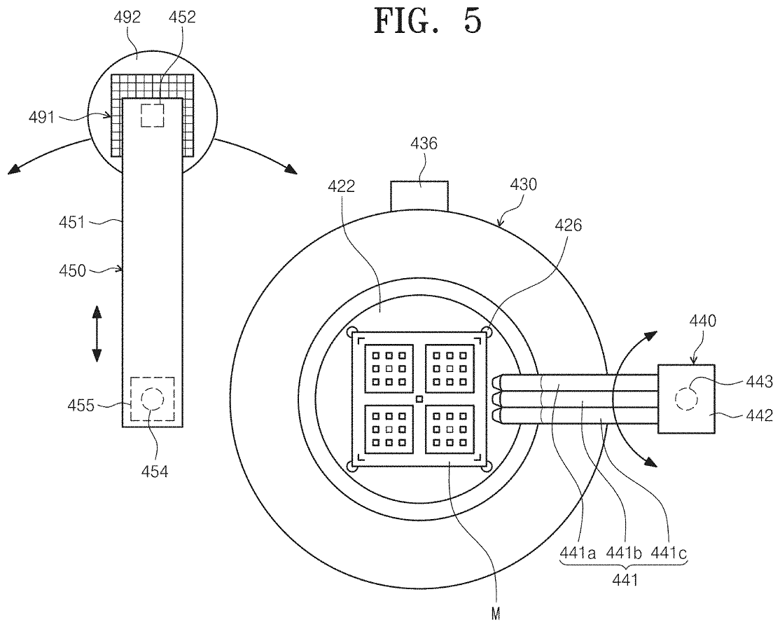

FIG. 4 is a diagram schematically illustrating an exemplary embodiment of the liquid treating chamber of FIG. 2 and FIG. 5 is a diagram illustrating the liquid treating chamber of FIG. 4 viewed from the top. Referring to FIG. 4 and FIG. 5, the liquid treating chamber 400 may include a housing 410, a support unit 420, a bowl 430, a liquid supply unit 440, a heating unit 450, and a coordinate unit 490.

The housing 410 may have an internal space 412. The housing 410 may have the internal space 412 in which the bowl 430 is provided. The housing 410 may have the internal space 412 in which the liquid supply unit 440 and the heating unit 450 are provided. A load/unload port (not illustrated) through which the substrate M may be loaded and unloaded may be formed in the housing 410. The load/unload port may be selectively opened/closed by a door (not illustrated). Further, an inner wall surface of the housing 410 may be coated with a material having corrosion resistance to a chemical supplied by the liquid supply unit 440. An exhaust hole 414 may be formed in a bottom surface of the housing 410. The exhaust hole 414 may be connected to an exhaust member such as a pump capable of exhausting the internal space 412. Therefore, a fume which may be generated in the internal space 412 may be exhausted through the exhaust hole 414. The support unit 420 may support the substrate M in a treating space 431 which the bowl 430 to be described below has. The support unit 420 may support the substrate M. The support unit 420 may rotate the substrate M.

The support unit 420 may include a chuck 422, a support axis 424, a driving member 425, and a support pin 426. The support pin 426 may be installed in the chuck 422. The chuck 422 may have a plate shape having a predetermined thickness. The support axis 424 may be coupled to a lower portion of the chuck 422. The support axis 424 may be a hollow axis. Further, the support axis 424 may be rotated by the driving member 425. The driving member 425 may be a hollow motor. When the driving member 425 rotates the support axis 424, the chuck 422 coupled to the support axis 424 may be rotated. The substrate M placed on the support pin 426 installed in the chuck 422 may be rotated with rotation of the chuck 422.

The support pin 426 may support the substrate M. The support pin 426 may include a plurality of support pins 426. The plurality of support pins 426 may be arranged in a substantially circular shape when viewed from the top. The support pin 426 may have a shape in which a portion corresponding to the corner zone of the substrate M is indented downward when viewed from the top. The support pin 426 may include a first face supporting a lower portion of the corner zone of the substrate M and a second face facing a side portion of the corner zone of the substrate M so as to restrict lateral movement of the substrate M when the substrate M is rotated. At least one support pin 426 may be provided. A plurality of support pins 426 may be provided. The support pins 426 may be provided in a number corresponding to number of corner zones of the substrate M having the square shape. The support pin 426 supports the substrate M to make the bottom of the substrate M and the top of the chuck 422 be spaced apart from each other.

The bowl 430 may have a cylindrical shape of which the upper portion is opened. The bowl 430 may have the treating space 431, and the substrate M may be liquid-treated and heating-treated within the treating space 431. The bowl 430 may prevent the treatment liquid supplied to the substrate M from being scattered and transmitted to the housing 410, the liquid supply unit 440, and the heating unit 450.

The bowl 430 may include a bottom portion 433, a vertical portion 434, and an inclination portion 435. A hole into which the support axis 424 may be inserted may be formed in the bottom portion 433 when viewed from the top. The vertical portion 434 may extend from the bottom portion 433 in the third direction Z. The inclination portion 435 may extend toward the substrate M supported on the support unit 420. The inclination portion 435 may extend to be inclined upward from the vertical portion 434. The inclination portion 435 may extend to be inclined upward toward the substrate M from the vertical portion 434. A discharge hole 432 through which the treatment liquid supplied by the liquid supply unit 440 may be discharged to the outside may be formed in the bottom portion 433. Further, the bowl 430 may be coupled to the elevation member 436 and a location of the bowl 430 may be changed in the third direction Z. The elevation member 436 may be a driving device that moves the bowl 430 in the vertical direction. The elevation member 436 may move the bowl 430 upward while the liquid treatment and/or the heating treatment for the substrate M is performed, and move the bowl 430 downward when the substrate M is loaded into the internal space 412 or the substrate is unloaded from the internal space 412. The liquid supply unit 440 may supply the treatment liquid of liquid-treating the substrate W. The liquid supply unit 440 may supply the treatment liquid to the substrate W supported on the support unit 420. The treatment liquid may be an etching liquid or a rinse liquid. The etching liquid may be the chemical. The etching liquid may etch the pattern formed on the substrate M. The etching liquid may also be called etchant. The rinse liquid may clean the substrate M. The rinse liquid may be provided as a known chemical liquid.

The liquid supply unit 440 may include a nozzle 441, a fixation body 442, a rotational axis 443, and a rotational member 444.

The nozzle 411 may supply the treatment liquid to the substrate M supported on the support unit 420. One end of the nozzle 411 may be coupled to the fixation body 442, and the other end of the nozzle 411 may extend toward the substrate M from the fixation body 442. The nozzle 411 may extend from the fixation body 442 in the first direction X. The other end of the nozzle 411 may be bent and extended at a predetermined angle toward the substrate M supported on the support unit 420.

The nozzle 411 may include a first nozzle 411a, a second nozzle 411b, and a third nozzle 411c. Any one of the first nozzle 411a, the second nozzle 411b, and the third nozzle 411c may supply the chemical C among the treatment liquids. The one of the first nozzle 411a, the second nozzle 411b, and the third nozzle 411c may supply the rinse liquid R among the treatment liquids. Further, another one of the first nozzle 411a, the second nozzle 411b, and the third nozzle 411c may supply a different type of chemical C from the chemical C supplied by any one of the first nozzle 411a, the second nozzle 411b, and the third nozzle 411c.

The fixation body 442 may support the nozzle 441. The fixation body 442 may fix the nozzle 441. The fixation body 442 may be coupled to the rotational axis 443 which is rotated around the third direction Z by the rotational member 444. When the rotational member 444 rotates the rotational axis 443, the fixation body 442 may be rotated around the third direction Z. Therefore, an ejection port of the nozzle 441 may be moved between a liquid supply location of supplying the treatment liquid to the substrate M and a waiting location which is a location not supplying the treatment liquid to the substrate M.

The heating unit 450 may heat the substrate M. The heating unit 450 may heat a specific location of the substrate M by irradiating a laser L to the specific location on the substrate M supported on the support unit 420. The heating unit 450 may swingably move between the specific location of the substrate M and a waiting location which deviates from the substrate M. The heating unit 450 may heat a partial zone of the substrate M. The heating unit 450 may heat the substrate M to which the chemical C is supplied and in which a liquid layer is formed. The heating unit 450 may heat the pattern formed on the substrate M. The heating unit 450 may heat a partial pattern of the pattern formed on the substrate M. The heating unit 450 may heat any one of the first pattern P1 and the second pattern P2. For example, the heating unit 450 may heat the second pattern P2 of the first pattern P1 and the second pattern P2. That is, the specific location of the substrate M may be any one of the first pattern P1 and the second pattern P2. As an example, the specific location of the substrate M may the second pattern P2.

The heating unit 450 may include a body 451, a driver 453, a shaft 454, a movement member 455, a laser module 460, an image module 470, and an optical module 480. The body 451 may be a container having an installation space therein. The laser module 460, the image module 470, and the optical module 480 to be described below may be installed in the body 451. Further, the body 451 may include an irradiation end portion 452. The laser L irradiated by the laser module 460 to be described below may be irradiated to the substrate M through the irradiation end portion 452. Further, light irradiated by an illumination member 472 to be described below may be provided through the irradiation end portion 452. Further, image photographing of an image acquiring member 471 to be described below may be achieved through the irradiation end portion 452. The irradiation end portion 452 may be disposed at one end of the body 451, and the shaft 454 to be described below may be coupled to the other end of the body 451.

The driver 453 may be a motor. The driver 453 may be coupled to the shaft 454. Further, the shaft 454 may be coupled to the body 451. The shaft 454 may be coupled to the body 451 via the movement member 455. The driver 453 may rotate the shaft 454. When the shaft 454 is rotated, the body 451 may be rotated. Therefore, a location of the irradiation end portion 452 of the body 451 may be changed. For example, the location of the irradiation end portion 452 may be changed with the third direction Z as the rotational axis. When viewed from the top, a center of the irradiation end portion 452 may move while drawing an arc around the shaft 454. That is, the heating unit 450 may be swingably moved based on a central axis of the shaft 454. The shaft 454 may be provided to a swing movement axis when the heating unit 450 is swingably moved. When viewed from the top, the irradiation end portion 452 may be moved so that the center of the irradiation end portion 452 passes through the center of the substrate M supported on the support unit 420. The irradiation end portion 452 may be moved between a heating location of irradiating the laser L to the substrate M and a waiting location of waiting when the substrate M is not heated. Further, the driver 453 may move the shaft 454 upward/downward. That is, the driver 453 may change the location of the irradiation end portion 452 upward/downward. Further, a plurality of driver 453 is provided, and any one may be provided as a rotary motor that rotates the shaft 454 and the other one may be provided as a linear motor that moves the shaft 454 upward/downward.

The movement member 455 may be provided between the shaft 4554 and the body 451. The movement member 455 may be an LM guide. The movement body 455 may move the body 451 in a lateral direction. The movement member 455 may move the body 451 in the first direction X and/or the second direction Y. The location of the irradiation end portion 452 of the heating unit 450 may be variously modified by the movement member 455 and the driver 453.

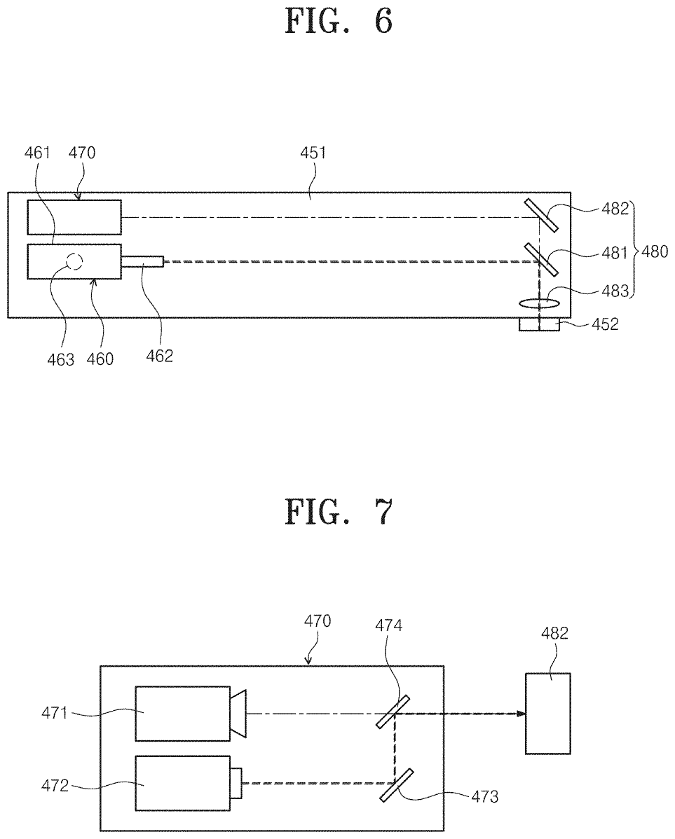

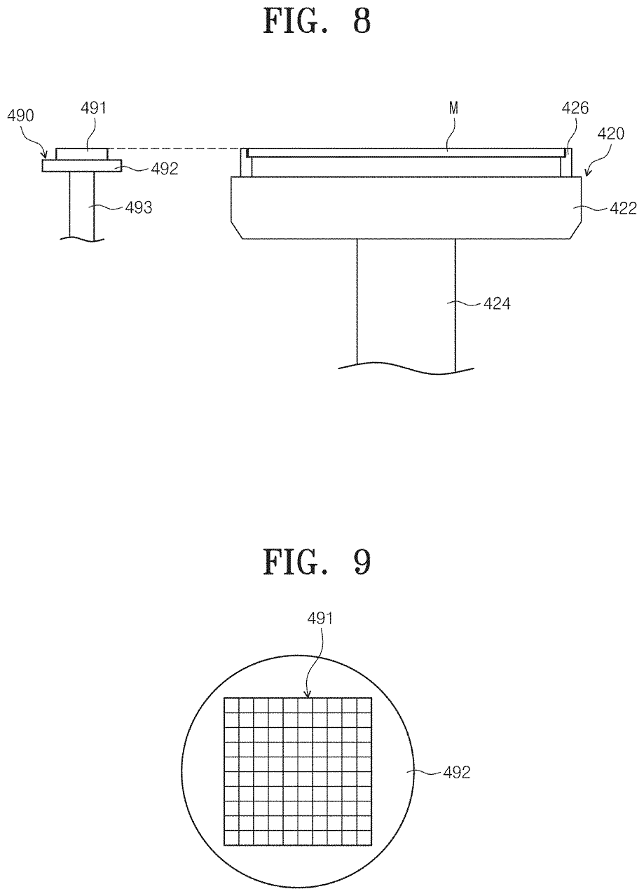

FIG. 6 is a diagram illustrating a view of a body of a heating unit, a laser module, an image module, and an optical module of FIG. 4 and FIG. 7 is a diagram illustrating the image module of FIG. 6 viewed from the top.

Referring to FIG. 6 and FIG. 7, a laser irradiation unit 461, a beam expander 462, and a tilting member 463 may be installed in the body 451. Further, the image module 470 may be installed in the body 451. Further, the optical module 480 may be installed in the body 451.

The laser module 460 may include the laser irradiation unit 461, the beam expander 462, and the tilting member 463. The laser irradiation unit 461 may irradiate the laser L. The laser irradiation unit 461 may irradiate the laser L having straightness. A shape, a profile, etc., of the laser L irradiated by the laser irradiation unit 461 may be adjusted by the beam expander 462. For example, a diameter of the laser L irradiated by the laser irradiation unit 461 may be changed by the beam expander 462. The diameter of the laser L irradiated by the laser irradiation unit 461 may be expanded or reduced by the beam expander 462. The tilting member 463 may tilt an irradiation direction of the laser L irradiated by the laser irradiation unit 461. For example, the tilting member 463 may tilt an irradiation direction of the laser L irradiated by the laser irradiation unit 461 by rotating the laser irradiation unit 461 around one axis. The tilting member 463 may include the motor.

The image module 470 may monitor the laser L irradiated by the laser irradiation unit 461. The image module 470 may include an image acquiring member 471, an illumination member 472, a first reflection plate 473, and a second reflection plate 474. The image acquiring member 471 may acquire an image for the substrate M and/or a coordinate system 491 of a coordinate unit 490 to be described below. The image acquiring member 471 may be a camera. The image acquiring member 471 may be a vision. The image acquiring member 471 may acquire an image including a spot to which the laser L irradiated by the laser irradiation unit 461 is irradiated.

The illumination member 472 may provide light so as to easily perform image acquisition of the image acquisition member 471. The light provided by the illumination member 472 may be sequentially reflected along the first reflection plate 473 and the second reflection plate 474.

The optical module 480 may allow the irradiation direction of the laser L irradiated by the laser irradiation unit 461, a photographing direction of acquiring the image by the image acquiring member 471, and the irradiation direction of the light provided by the illumination member 472 to have the same axis when viewed from the top. The illumination member 472 may transmit the light to a zone to which the laser L is irradiated by the optical module 480. Further, the image acquiring member 471 may acquire an image such as a video/a photo for the zone to which the laser L is irradiated in real time. The optical module 480 may include a first reflection member 481, a second reflection member 482, and a lens 483.

The first reflection member 481 may change the irradiation direction of the laser L irradiated by the laser irradiation unit 461. For example, the first reflection member 481 may change the irradiation direction of the laser L irradiated in the horizontal direction to a vertical downward direction. Further, the laser L refracted by the first reflection member 481 may be transmitted to the substrate M as the treated object by sequentially passing through the lens 483 and the irradiation end portion 452.

The second reflection member 482 may change the photographing direction of the image acquiring member 471. For example, the second reflection member 482 may change the photographing direction of the image acquiring member 471 which is the horizontal direction to the vertical downward direction. Further, the second reflection member 482 may change the irradiation direction of the light of the illumination member 472 transmitted through the first reflection plate 473 and the second reflection plate 474 in sequence from the horizontal direction to the vertical downward direction.

In addition, the first reflection member 481 and the second reflection member 482 may be provided at the same location when viewed from the top. Further, the second reflection member 482 may be disposed above the first reflection member 481. Further, the first reflection member 481 and the second reflection member 482 may be tilted at the same angle.

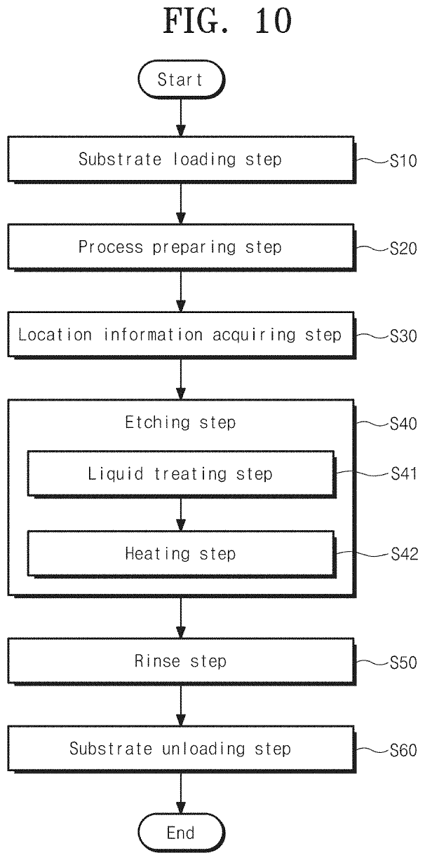

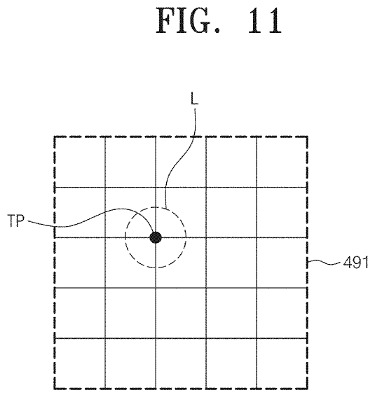

FIG. 8 is a diagram illustrating a coordinate unit and a support unit of the liquid treating chamber of FIG. 4, and FIG. 9 is a diagram illustrating the coordinate unit of FIG. 8 viewed from the top.

Referring to FIG. 8 and FIG. 9, the coordinate unit 490 may identify whether an error between the irradiation location of the laser L and a predetermined target position TP occurs. For example, the coordinate unit 490 may be provided in the internal space 412. Further, when the irradiation end portion 452 is at the waiting location, the coordinate unit 490 may be installed in a zone below the irradiation end portion 452. The coordinate unit 490 may include the coordinate system 491, a plate 492, and a support frame 493.

The coordinate system 491 may also be called a global coordinate system. The coordinate system 491 may be provided as a line grid. Coordinates of a central location A of the coordinate system 491 may be (0,0). The coordinate system 491 may be disposed below the irradiation end portion 452 of the heating unit 450 when the heating unit 450 is at the waiting location. The predetermined target position TP may be marked in the coordinate system 491. Further, the coordinate system 491 may include a scale to identify the error between the target position TP and the irradiation location to which the laser L is irradiated. Further, the coordinate system 491 may be installed on the plate 492. The plate 492 may be supported by the support frame 493. A height of the coordinate system 491 determined by the plate 492 and the support frame 493 may be the same as a height of the substrate M supported on the support unit 420. For example, a height from the bottom surface of the housing 410 up to the top surface of the coordinate system 491 may be equal to a height from the bottom surface of the housing 410 up to the top surface of the substrate M supported on the support unit 420. This is to make the height of the irradiation end portion 452 when identifying the error by using the coordinate unit 490 and the height of the irradiation end portion 452 when heating the substrate M be equal to each other. When the irradiation direction of the laser L irradiated by the laser irradiation unit 461 is slightly mismatched with the third direction Z, the irradiation location of the laser L may vary depending on the height of the irradiation end portion 452, so the coordinate system 491 may be provided at the same height as the substrate M supported on the support unit 420. Hereinafter, a method for treating a substrate according to an exemplary embodiment of the present invention will be described in detail. The substrate treating method described below may be performed by the liquid treating chamber 400. Further, the controller 30 may control components provided in the liquid treating chamber 400 so that the liquid treating chamber 400 may perform the substrate treating method described below. For example, the controller 30 may generate a control signal for controlling at least any one of the support unit 420, the elevation member 436, the liquid supply unit 440, and the heating unit 450 so that components of the liquid treating chamber 400 may perform the substrate treating method described below.

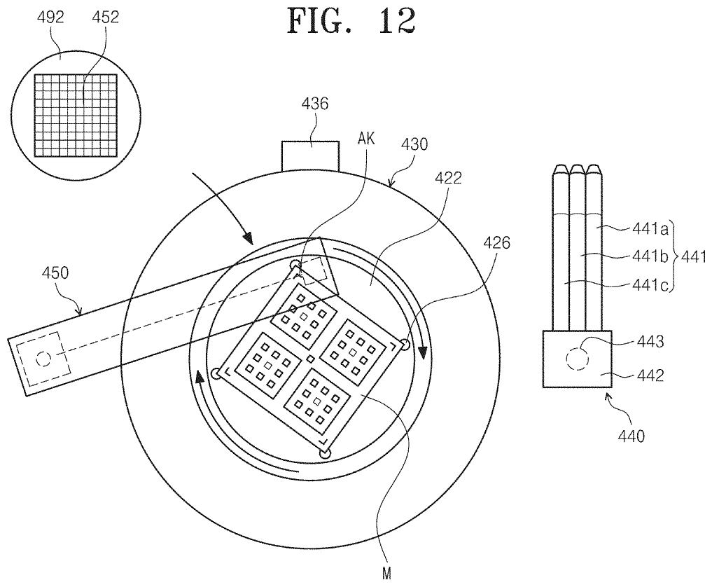

FIG. 10 is a flowchart illustrating a method for treating a substrate according to an exemplary embodiment of the present invention.

Referring to FIG. 10, the substrate treating method according to an exemplary embodiment of the present invention may include a substrate loading step S10, a process preparing step S20, a location information acquiring step S30, an etching step S40, a rinse step S50, and a substrate unloading step S60.

In the substrate loading step S10, the door may open the load/unload port formed in the housing 410. Further, the in the substrate loading step S10, the transfer robot 320 may seat the substrate M on the support unit 420. While the transfer robot 320 seats the substrate M on the support unit 420, the elevation member 436 may descend the location of the bowl 430.

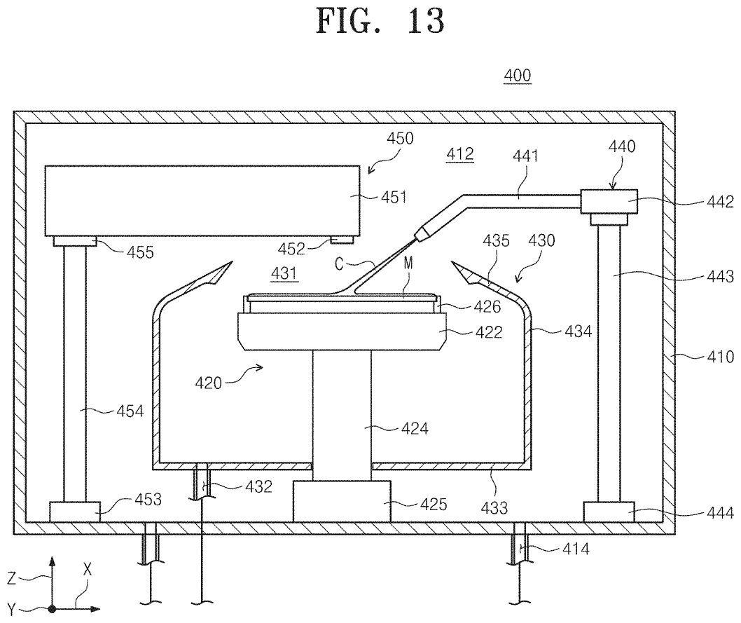

The process preparing step S20 may be performed after the loading of the substrate M is completed. In the process preparing step S20, it may be identified whether the error occurs at the irradiation location of the laser L irradiated to the substrate M. For example, in the process preparing step S20, the laser module 470 may irradiate a test laser L to the coordinate system 491 of the coordinate unit 490. When the test laser L irradiated by the laser module 470 matches the predetermined target position TP marked in the coordinate system 491 as illustrated in FIG. 11, it may be determined that the mismatch does not occur in the laser irradiation unit 461, and the following location information acquiring step S30 may be performed. Further, in the process preparing step S20, it may be identified whether the error occurs the irradiation location of the laser L, and the components of the liquid treating chamber 400 may be restored to an initial state.

Further, the process preparing step S20 may include a step of calculating a first length R of the heating unit 450.

In the location information acquiring step S30, the location of the substrate M may be identified. In the location information acquiring step S30, the location information of the patterns on the substrate M may be acquired. That is, in the location information acquiring step S30, information on the location of the substrate M to which the chemical C and the rinse liquid R are to be supplied, and the location of the pattern to which the laser L is to be irradiated may be acquired. The location information in the location information acquiring step S30 may include information on a coordinate for the center of the substrate M, and a coordinate for the location of the pattern.

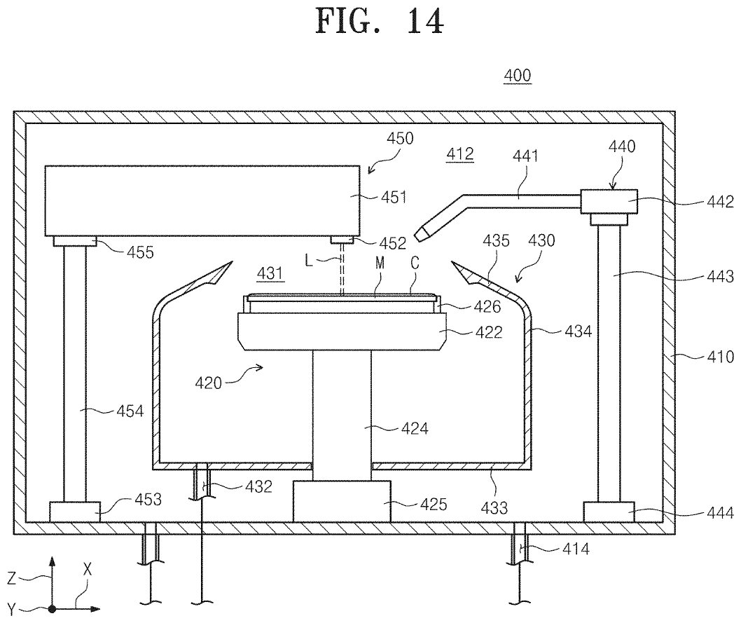

The location information acquiring step S30 may be performed by moving the irradiation end portion 452 of the heating unit 450 between the waiting location and the heating location, and rotating the substrate M in one direction by the support unit 420. When the irradiation end portion 452 is moved and the substrate M is rotated in one direction, the irradiation end portion 452 and the reference mark AK may match each other at a specific time as illustrated in FIG. 12. In this case, the image module 470 may acquire an image for the reference mark AK. The controller 30 may acquire a coordinate value for the reference mark AK through the image acquired by the image module 470. Further, the controller 30 may prestore coordinate data regarding left and right dimension of the substrate M, and a center point of the substrate M, and coordinate data regarding the locations of the first pattern P1, the second pattern P2, and the exposure pattern EP in the substrate M. The controller 30 may acquire location information regarding the center point of the substrate M, the first pattern P1, and the second pattern P2 based on the acquired coordinate value for the reference mark AK, and the above-described prestored data.

In the etching step S40, etching the pattern formed on the substrate M may be performed. In the etching step S40, etching the pattern formed on the substrate M may be performed so that the CDs of the first pattern P1 and the second pattern P2 match each other. The etching step S40 may be a CD correction process of correcting a difference between the CDs of the first pattern P1 and the second pattern P2. The etching step S40 may include a liquid treating step S41 and a heating step S42.

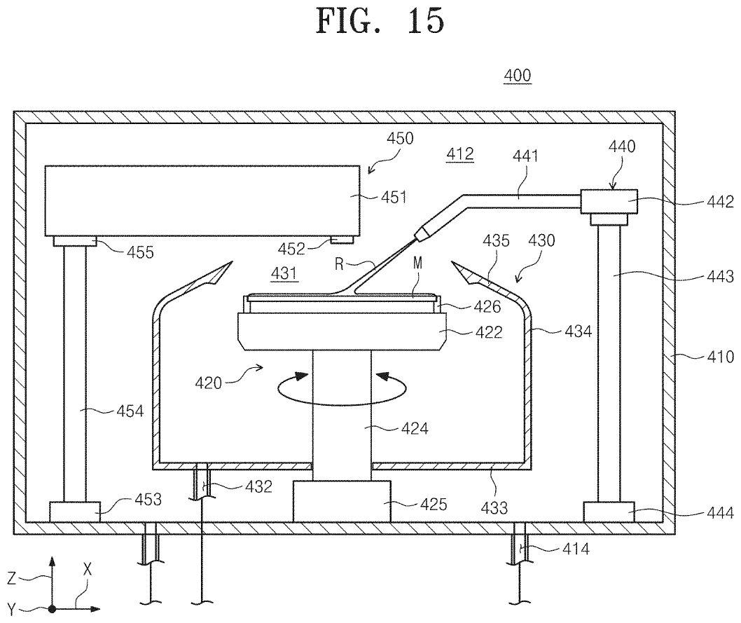

The liquid treating step S41 may be a step in which the liquid supply unit 440 supplies the chemical C which is the etchant to the substrate M as illustrated in FIG. 13. In the liquid treating step S41, the support unit 420 may not rotate the substrate M. In the heating step S42 to be described below, in order to accurately irradiate the laser L in a specific pattern, the mismatch of the location of the substrate M should be minimized, and this reason is that the location of the substrate M may be mismatched when rotating the substrate M. Further, the amount of the chemical C supplied in the liquid treating step S41 may be supplied enough to form a puddle. For example, the amount of the chemical C supplied in the liquid treating step S41 may cover the entirety of the top surface of the substrate M, and the chemical C may be provided so as not to flow down from the substrate or so that the amount is not large even though the chemical C flows down. As necessary, the nozzle 441 may also supply the etching liquid to the entirety of the top surface of the substrate M while changing the location thereof.

In the heating step S42, the substrate M may be heated by irradiating the laser L to the substrate M. In the heating step S42, the substrate M may be heated by irradiating the laser L to the substrate M in which the liquid layer is formed by supplying the chemical C. In the heating step S42, the laser L may be irradiated to a specific zone of the substrate M. A temperature of the specific zone to which the laser L is irradiated may be raised. Therefore, an etching degree of the zone to which the laser L is irradiated by the chemical C may be increased. Further, in he heating step S42, the laser L may be irradiated to any one of the first pattern P1 and the second pattern P2. For example, the laser L may be irradiated to only the second pattern P2 of the first pattern P1 and the second pattern P2. Therefore, an etching ability of the chemical C for the second pattern P2 is enhanced. Therefore, the CD of the first pattern P1 may be changed from a first CD (e.g., 69 nm) to a target CD (e.g., 70 nm). Further, the CD of the second pattern P2 may be changed from a second CD (e.g., 68.5 nm) to the target CD (e.g., 70 nm). That is, the etching ability for a partial zone of the substrate M is enhanced to minimize a CD deviation of the patterns formed on the substrate M.

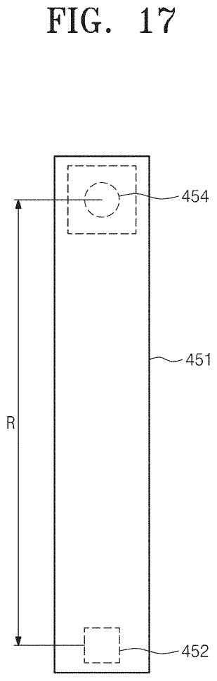

In the rinse step S50, a process by-product generated in the etching step S40 may be removed from the substrate M. In the rinse step S50, the rinse liquid R is supplied to the rotating substrate M to remove the process by-product formed on the substrate M as illustrated in FIG. 15. In order to dry the rinse liquid R which remains on the substrate M as necessary, the support unit 420 rotates the substrate M at a high speed to remove the rinse liquid R which remains on the substrate M.

In the substrate unloading step S60, the substrate M of which treating is completed may be unloaded from the internal space 412. In the substrate unloading step S60, the door may open the load/unload port formed in the housing 410. Further, in the substrate unloading step S60, the transfer robot 320 may unload the substrate M from the support unit 420, and unload the unloaded substrate M from the internal space 412.

Hereinafter, the method for calculating the first length R of the heating unit 450 will be described in detail.

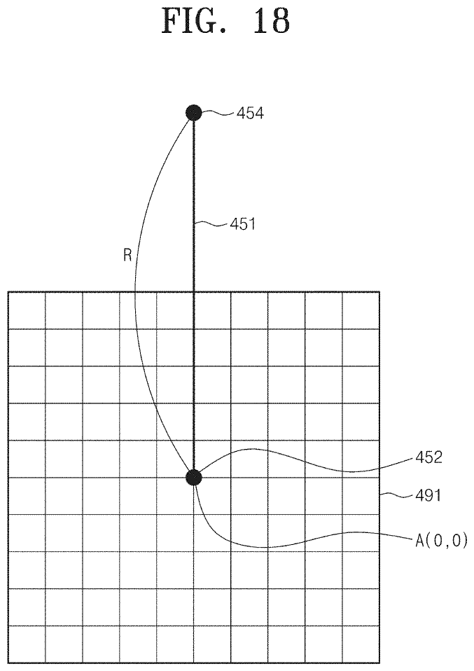

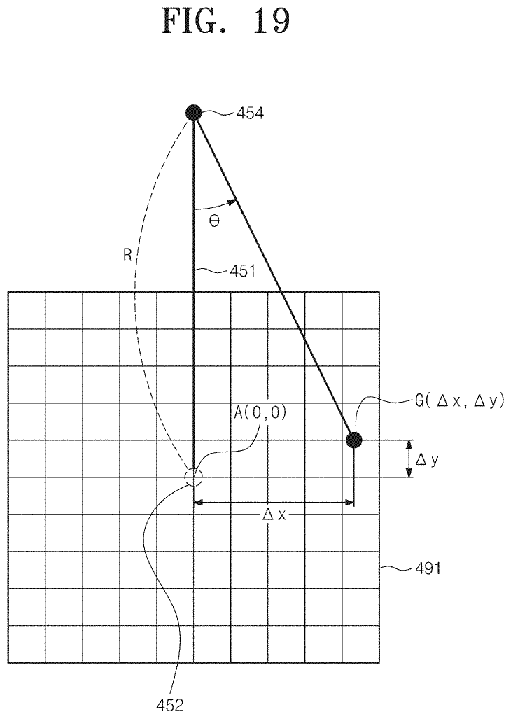

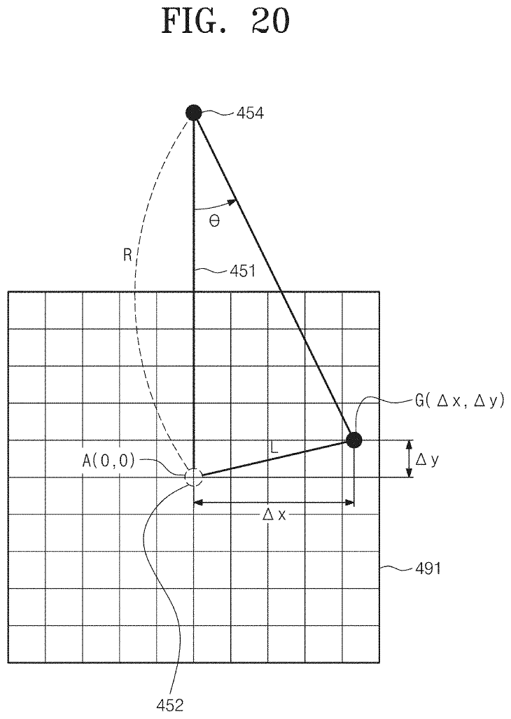

FIG. 16 is a flowchart schematically illustrating a method for calculating a first length of a heating unit, FIG. 17 is a diagram illustrating the first length of the heating unit, and FIGS. 18 to 20 are diagrams schematically illustrating each step of FIG. 16.

The method for calculating the first length R of the heating unit 450 may be performed by the image module 470. The method for calculating the first length R of the heating unit 450 may be performed by the image acquiring member 471. The method for calculating the first length R of the heating unit 450 may be performed by the image module 470 and the controller 30.

Referring to FIG. 16, the method for calculating the first length R of the heating unit 450 (a swing arm length calculating method) may include a step S21 of matching a central coordinate A of the coordinate system 491 and a central axis of the irradiation end portion 452 of the heating unit 450.

The first length R of the heating unit 450 may mean a length in which the body 451 swingably moves based on a swing movement axis of the shaft 454. As an example, referring to FIG. 17, a first length L may mean a distance between the swing movement axis of the shaft 454 and the central axis of the irradiation end portion 452. In FIGS. 18 to 20, the body 451 is illustrated as a straight line, and the irradiation end portion 452 and the shaft 454 are schematically illustrated as a circular shape for convenience of description. Referring to FIGS. 16 and 18, the method for calculating the first length R of the heating unit 450 (the swing arm length calculating method) may include a step S21 of aligning the centers of the coordinate system 491 and the heating unit 450. Aligning the centers of the coordinate system 491 and the heating unit 450 means matching the central location A of the coordinate system 491 and the central axis of the irradiation end portion 452 of the heating unit 450. Aligning the centers of the coordinate system 491 and the heating unit 450 means matching the central location A of the coordinate system 491 and the photographing direction (photographing axis) of the image module 470 photographed through the irradiation end portion 452. Through this, the method for calculating the first length R of the heating unit 450 (the swing arm length calculating method) may be performed through the image module 470.

The coordinate unit 490 may be disposed below the irradiation end portion 452 of the heating unit 450 when the heating unit 450 is at the waiting location. In this case, the central axis of the irradiation end portion 452 of the heating unit 450 and the central location A of the coordinate system 491 may match each other. However, when the central axis of the irradiation end portion 452 of the heating unit 450 and the central location A of the coordinate system 491 do not match each other, the central axis of the irradiation end portion 452 and the central location A of the coordinate system 491 are aligned with each other. Therefore, the photographing axis of the image module 470 may match the central location A of the coordinate system 491.

Referring to FIGS. 16 and 19, the method for calculating the first length R of the heating unit 450 (the swing arm length calculating method) may include a step S22 of rotating the heating unit 450 at a predetermined first angle θ. The first length θ as a value set for calculating the first length R is provided as a previously known value. Further, the first angle θ is provided as an angle at which the irradiation end portion 452 is movable within the coordinate system 491.

Referring to FIGS. 16 and 20, the method for calculating the first length R of the heating unit 450 (the swing arm length calculating method) may include a step S23 of aligning a movement length L of the heating unit 450. The calculation of the movement distance L may be performed by the image module 470 which is provided inside of the heating unit 450, and has the same axis as the irradiation direction of the laser L irradiated by the laser module 460. The movement distance L may be calculated on the coordinate system 491. The image module 470 may first calculate a coordinate of a movement location G to which the central axis of the irradiation end portion 452 moved at the first angle θ is positioned. The image module 470 may calculate an X-axis direction movement distance Δx from the coordinate (0, 0) of the central location A and a y-axis direction movement Δy from the coordinate (0, 0) of the central location A of the coordinate system 491. In this case, the coordinate of the movement location G to which the central axis of the irradiation end portion 452 moved at the first angle θ is positioned may be (Δx, Δy). When the coordinate of the movement location G is derived, the image module 470 may calculate the movement distance L. The movement distance L may be a straight distance between the coordinate (0, 0) of the central location A and the coordinate (Δx, Δy) of the movement location G. The movement distance L may be calculated through a known equation.

Referring to FIGS. 16 and 20, the method for calculating the first length R of the heating unit 450 (the swing arm length calculating method) may include a step S24 of calculating the first length R (swing arm length) of the heating unit 450. The image module 470 may calculate the first length R (swing arm length) of the heating unit 450 through the movement distance L. The first length R (swing arm length) may be calculated through the following equation. However, the first length R is not limited thereto, and may be calculated by another known equation.

$$R = \frac{L}{2 sin ( \frac{θ}{2} )} \qquad 〈 Equation 〉$$

It is necessary to precisely control the heating unit 450 in order to irradiate the laser L to a specific location within the substrate M by using the heating unit 450 which is swingably moved. It is necessary to accurately know the length of the heating unit 450 (swing arm length) for reliable operation control of the heating unit 450. In general, the swing arm length is provided as a previously known value. However, a designed value and an actual length value of the swing arm are different from each other due to a tolerance which occurs during a manufacturing process of the swing arm or during a process of installing an instrument in the chamber, so the error occurs. In order to correct the error, measuring an actual length R of the swing arm is required. Further, the accurate measurement of the length R is required even for the reliable operation control of the swing arm. Therefore, according to the exemplary embodiment of the present invention, a movement amount of on the coordinate system may be measured through the image module when the swing arm rotates, and the swing arm length may be calculated through the movement amount. Through this, it is possible to precisely control the swing arm, and furthermore, it is possible to accurately the laser to a specific location on the substrate through the swing arm.

The foregoing detailed description illustrates the present invention. Further, the above content shows and describes the exemplary embodiment of the present invention, and the present invention can be used in various other combinations, modifications, and environments. That is, the foregoing content may be modified or corrected within the scope of the concept of the invention disclosed in the present specification, the scope equivalent to that of the disclosure, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed embodiment. Further, the accompanying claims should be construed to include other exemplary embodiments as well.

1. An apparatus for treating a substrate, the apparatus comprising:
a support unit supporting a substrate;
a liquid supply unit supplying a treatment liquid to the substrate supported on the support unit;
a heating unit heating a specific location of the substrate by irradiating a laser to the specific location on the substrate supported on the support unit, and swingably moved between the specific location of the substrate, and a waiting location of deviating from the substrate;
a coordinate unit disposed below an irradiation end portion to which the laser is irradiated from the heating unit when the heating unit is positioned at the waiting location; and
an image module monitoring the laser irradiated from the heating unit,
wherein the image module calculates a movement distance in which the heating unit is swingably moved on the coordinate unit, and measures a first length in a longitudinal direction of the heating unit.

2. The apparatus of claim 1, wherein the heating unit includes
a body having one end at which the irradiation end portion is disposed,
a driver providing power for swingably moving the body, and
a shaft disposed between the body and the driver, and providing a swing movement axis of the body, and
the first length is a length in which the body is swingably moved based on the swing movement axis of the shaft.

3. The apparatus of claim 1, wherein the heating unit includes
a body having one end at which the irradiation end portion is disposed,
a driver providing power for swingably moving the body, and
a shaft disposed between the body and the driver, and providing a swing movement axis of the body, and
the first length is a distance between the swing movement axis of the shaft and a central axis of the irradiation end portion.

4. The apparatus of claim 2, wherein the shaft is coupled to the other end of the body.

5. The apparatus of claim 2, wherein the heating unit further includes a laser module provided inside the body, and irradiating the laser, and
the image module, and
the image module is provided inside the body, and has the same axis as an irradiation direction of the laser of the laser module.

6. The apparatus of claim 2, wherein the coordinate unit includes
a coordinate system in which a top surface is disposed on the same plane as the top surface of the substrate supported on the support unit, and
a support frame supporting the coordinate system.

7. The apparatus of claim 6, wherein the heating unit swingably moves the heating unit at a predetermined first angle while the central axis of the irradiation end portion and the central location of the coordinate system.

8. The apparatus of claim 7, wherein the coordinate of the central location of the coordinate system is (0, 0).

9. The apparatus of claim 7, wherein the heating unit which is swingably moved at the first angle on the coordinate system has a movement coordinate,
the movement coordinate is a coordinate of a location in which the central axis of the irradiation end portion of the heating unit is positioned on the coordinate system, and
the image module measures the movement coordinate.

10. The apparatus of claim 9, wherein the image module calculates the movement distance in which the central axis of the irradiation end portion of the heating unit is moved by using the movement coordinate.

11. The apparatus of claim 10, wherein the image module calculates the first length by using the first angle and the movement distance.

12. The apparatus of claim 11, wherein the first length is calculated through the following equation.
(Here, R represents the first length, L represents the movement distance, and θ represents the first angle.)
$$R = \frac{L}{2 sin ( \frac{θ}{2} )} \qquad 〈 Equation 〉$$

13. The apparatus of claim 6, wherein the coordinate system is provided as a line grid.

14. The apparatus of claim 1, wherein in the substrate, a first pattern formed in a plurality of cells and a second pattern different from the first pattern outside a zone where the plurality of cells is formed, and
he specific location of the substrate is the second pattern.

15. The apparatus of claim 14, further comprising:
a controller,
wherein the controller controls the heating unit so as to minimize a deviation between critical dimensions of the first pattern and the second pattern by irradiating the light to the second pattern.

16.-20. (canceled)

21. An apparatus for treating a substrate, the apparatus comprising:
a support unit supporting a substrate;
a liquid supply unit supplying a treatment liquid to the substrate supported on the support unit;
a heating unit heating a specific location of the substrate by irradiating a laser to the specific location on the substrate supported on the support unit, and swingably moved between the specific location of the substrate, and a waiting location of deviating from the substrate; and
a coordinate unit disposed below an irradiation end portion to which the laser is irradiated from the heating unit when the heating unit is positioned at the waiting location,
wherein the heating unit includes
a body having one end at which the irradiation end portion is disposed,
a driver providing power for swingably moving the body,
a shaft disposed between the body and the driver, and providing a swing movement axis of the body,
a laser module provided inside the body, and irradiating the laser, and
an image module provided inside the body, and monitoring the laser irradiated from the heating unit, and having the same axis as an irradiation direction of the laser of the laser module,
the image module calculates a movement distance in which the heating unit is swingably moved on the coordinate unit at a predetermined first angle, and calculates a first length in a longitudinal direction of the heating unit.
